(19) United States
(12) Patent Application Publication
(10) Pub. No.: US 2021/0080821 A1
(43) Pub. Date: Mar. 18, 2021

(54) ULTRAVIOLET RAY MASK AND MANUFACTURING METHOD THEREOF

(71) Applicant: SHENZHEN CHINA STAR OPTOELECTRONICS TECHNOLOGY CO., LTD, Shenzhen, Guangdong (CN)

(72) Inventor: Wanchun WU, Shenzhen, Guangdong (CN)

(21) Appl. No.: 16/069,317

(22) PCT Filed: Jun. 1, 2018
(86) PCT No.: PCT/CN2018/089653

§ 371 Date: Jul. 11, 2018

(30) Foreign Application Priority Data
May 9, 2018 (CN) 201810438871.X

(51) Int. Cl. G03F 1/38; G02F 1/157; G02F 1/163; G02F 1/1524; G02F 1/1516; G02F 1/155; G03F 1/48

(52) U.S. Cl. CPC G03F 1/38; G02F 1/157; G02F 1/163; G02F 2001/1635; G02F 1/15165; G02F 1/155; G03F 1/48; G02F 1/1524

(57) ABSTRACT

Disclosed is an ultraviolet ray mask, comprising a first polarizer and a second polarizer, which are oppositely arranged and an electrochromic glass disposed between the first polarizer and the second polarizer, and the electrochromic glass comprises a first substrate closer to the first polarizer and a second substrate closer to the second polarizer; a first electrode layer is provided on a surface of the first substrate facing the second substrate, and thin film transistors in an array and a second electrode layer disposed on the thin film transistors are provided on a surface of the second substrate facing the first substrate, and a transmittance of the electrochromic glass changes after a voltage is applied to the first electrode layer and the second electrode layer. Further disclosed is a manufacturing method of an ultraviolet ray mask.

### FIELD OF THE INVENTION

The present invention relates to a display technology field, and more particularly to an ultraviolet ray mask and a manufacturing method thereof.

### BACKGROUND OF THE INVENTION

A display device such as a liquid crystal display (LCD) is a widely used flat display device. The manufacturing method thereof generally includes: providing two parallel substrates and coating a sealant between the two substrates. The liquid crystal is filled in the space formed by the sealant and the two base substrates. Thin Film Transistors (TFT) are disposed on the lower substrate, and color filters (CF) are disposed on the upper substrate. The rotation directions of the liquid crystal molecules in the liquid crystal cell is controlled by changing the signal and voltage on the TFT, so as to achieve the purpose of controlling whether the polarized light of each pixel is emitted or not.

The liquid crystal is filled by the liquid crystal dropping in the existing liquid crystal processing technology. Since the sealant may come into contact with the liquid crystal before the sealant is cured, the industry generally adopts the UV (Ultraviolet ray) curing method to avoid the contamination of the liquid crystal due to the direct contact between the liquid crystal and the sealant. The UV curing is mainly to cover the liquid crystal area with an obstructer (mask, also referred to as a photomask), and to expose the area coated with the sealant to implement UV curing to the sealant with a UV curing device. This mask is a UV mask.

When the sealant is cured, correspondingly sized UV masks need to be developed for products of different sizes. For each size, the UV mask is used only once. The UV masks of products of all different sizes are independent. Every development of one product requires the development of a corresponding UV mask. This method will increase the production cost of the display device, which is not conducive to controlling the production cost of the LCD panel. Moreover, when the productions for different sizes are conducted, the UV masks need to be manually replaced. The replacement process is slow, and the risks such as fragmentation are easily caused during the replacement process.

### SUMMARY OF THE INVENTION

In view of the insufficiency of existing technologies, the present invention provides an ultraviolet ray mask and a manufacturing method thereof so that the mask can be compatible with products of different sizes, and the production cost of the panel is reduced to improve the panel production efficiency and to reduce the risk of fragmentation due to the replacement of the mask.

For realizing the aforesaid objective, the present invention provides the following technical solutions:

an ultraviolet ray mask, comprising a first polarizer and a second polarizer, which are oppositely arranged and an electrochromic glass disposed between the first polarizer and the second polarizer, wherein the electrochromic glass comprises a first substrate closer to the first polarizer and a second substrate closer to the second polarizer; a first electrode layer is provided on a surface of the first substrate facing the second substrate, and thin film transistors in an array and a second electrode layer disposed on the thin film transistors are provided on a surface of the second substrate facing the first substrate, and a transmittance of the electrochromic glass changes after a voltage is applied to the first electrode layer and the second electrode layer.

As one of the embodiments, the electrochromic glass comprises the first substrate, the second substrate, an electrochromic layer disposed between the first electrode layer and the second electrode layer, an electrolyte layer disposed between the electrochromic layer and the first electrode layer and an ion storage layer disposed between the electrochromic layer and the second electrode layer.

As one of the embodiments, the electrochromic layer is formed by tungsten trioxide.

As one of the embodiments, the electrochromic layer is formed by polythiophene and derivatives thereof, viologen, tetrathiafulvalene and metal phthalocyanine compound.

As one of the embodiments, the electrolyte layer is a solution or a solid electrolyte material containing lithium perchlorate or sodium perchlorate.

As one of the embodiments, the ion storage layer is formed by one of TiO2, CeO2, SnO2 and ZrO2.

As one of the embodiments, the ion storage layer is formed by one of NiOx, IrO2, CoO2, MnO2, FeO2, Cr2O3 and RhO2.

As one of the embodiments, the first electrode layer and the second electrode layer are formed by indium tin oxide.

As one of the embodiments, the ultraviolet ray mask further comprises two transparent protective layers respectively disposed between the first polarizer and the second substrate and between the second polarizer and the first substrate.

Another objective of the present invention is to provide a manufacturing method of the ultraviolet ray mask, comprising:

providing a first underlayer, and sequentially fabricating the thin film transistors and the second electrode layer on the first underlayer;

providing a second underlayer, and fabricating the first electrode layer on the second underlayer;

filling material between the first underlayer and the second underlayer to form the electrochromic glass; and

respectively forming the first polarizer and the second polarizer on outer surfaces of the first underlayer and the second underlayer.

The present invention provides the electrochromic glass with the thin film transistors and the electrode layers between two polarizers. By applying a voltage to the two electrode layers of the electrochromic glass, the transmittance of the electrochromic glass can be changed, so that the mask can be applied to products of various sizes, and the production cost of the panel is reduced to improve the panel production efficiency and to reduce the risk of fragmentation due to the replacement of the mask.

### BRIEF DESCRIPTION OF THE DRAWINGS

FIG. 1 is a structural diagram of an ultraviolet ray mask according to the embodiment of the present invention;

FIG. 2 is a structural diagram of a first substrate according to the embodiment of the present invention;

FIG. 3 is a structural diagram of a second substrate according to the embodiment of the present invention;

FIG. 4 is a diagram of a manufacturing method of an ultraviolet ray mask according to the embodiment of the present invention.

### DETAILED DESCRIPTION OF PREFERRED EMBODIMENTS

For the purpose, technical solutions and advantages of the present invention will become clear and unambiguous, the embodiment of the present invention is described in further detail below with reference to the accompanying drawings, simultaneously. It should be noted that the specific embodiments described herein are merely for explaining the present invention and are not intended to limit the present invention.

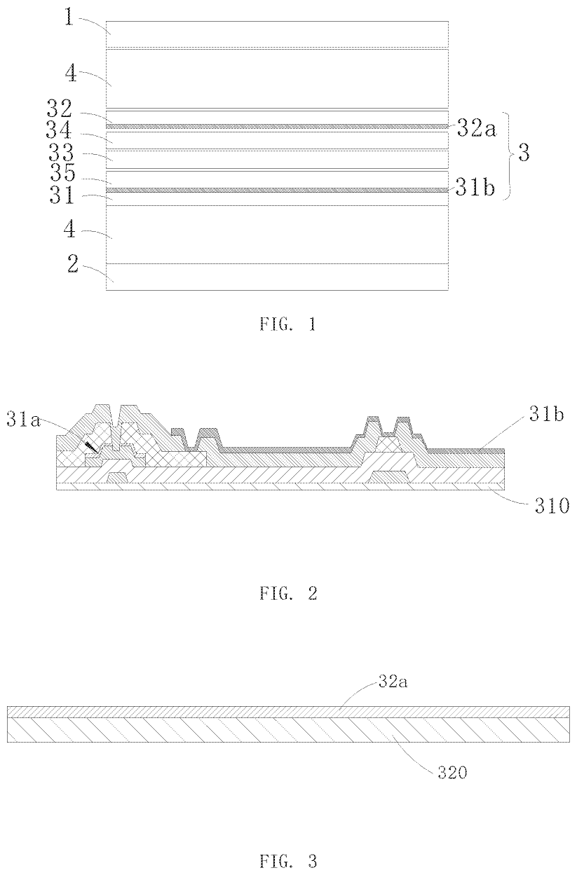

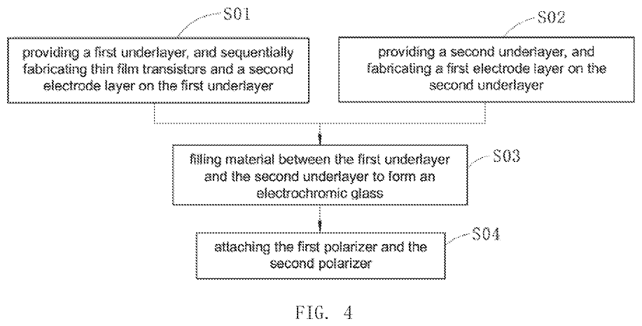

Please refer to FIG. 1 to FIG. 3. The ultraviolet ray mask according to the embodiment of the present invention mainly comprises a first polarizer 1 and a second polarizer 2, which are oppositely arranged and an electrochromic glass 3 disposed between the first polarizer 1 and the second polarizer 2, wherein the electrochromic glass 3 comprises a first substrate 31 closer to the first polarizer 1 and a second substrate 32 closer to the second polarizer 2; a first electrode layer 32a is provided on a surface of the first substrate 31 facing the second substrate 32, and thin film transistors 31a in an array and a second electrode layer 31b disposed on the thin film transistors 31a are provided on a surface of the second substrate 32 facing the first substrate 31, and a transmittance of the electrochromic glass 3 changes after a voltage is applied to the first electrode layer 32a and the second electrode layer 31b. The second substrate 32 functions like a thin film transistor array substrate in the prior art.

When all the thin film transistors 31a are kept in an operating state and turned on, the transmittance of the entire surface of the electrochromic glass 3 is consistent. Since the thin film transistors 31a are aligned in an array, the light transmittance of respective regions of the electrochromic glass 3 can be changed by individually controlling on and off of each thin film transistor 31a, After a voltage is applied to the first electrode layer 32a and the second electrode layer 31b, the local light transmittance of the electrochromic glass 3 can be changed by controlling on and off of the thin film transistors 31a in the corresponding area. Thus, the structure of the mask (photomask) similar to the prior art is formed, and the opaque portion serves as a shielding area, and the light-transmitting portion can allow UV light to pass through, thereby implementing the light curing to the sealing frame glue underneath.

In this embodiment, the electrochromic glass 3 specifically comprises the first substrate 31, the second substrate 32, an electrochromic layer 33 disposed between the first electrode layer 32a and the second electrode layer 31b, an electrolyte layer 34 disposed between the electrochromic layer 33 and the first electrode layer 32a and an ion storage layer 35 disposed between the electrochromic layer 33 and the second electrode layer 31b.

The electrochromic layer 33 can undergo an electrochemical redox reaction under the action of an external electric field, to gain or loss electrons to change the color of the material, thereby achieving the change in the transmittance. When the ultraviolet ray mask is operated, a certain voltage is applied between the first electrode layer 32a and the second electrode layer 31b, and the electrochromic layer 33 undergoes an electrochemical redox reaction under the action of the voltage to change the color thereof.

After the forward direct current voltage is applied to the electrolyte layer 34 in the region corresponding to the thin film transistor 31a, the ions in the ion storage layer 35 are extracted and passed through the ion conductor to enter the electrochromic layer 33 to achieve a power-free memory. After the reverse voltage is applied to the electrolyte layer 34, the ions in the electrochromic layer 33 are extracted and then enter the ion storage layer 35, and the electrochromic glass 3 returns to be transparent.

Here, a transparent glass substrate is used for both the first substrate 31 and the second substrate 32, and a transparent indium tin oxide conductive material is used for the first electrode layer 32a and the second electrode layer 31b. The electrochromic layer 33 may be an inorganic electrochromic material, such as tungsten trioxide, or may be an organic electrochromic material, such as polythiophene and derivatives thereof, viologen, tetrathiafulvalene and metal phthalocyanine compound. The electrolyte layer 34 is a solution or a solid electrolyte material containing lithium perchlorate or sodium perchlorate. The ion storage layer 35 serves to store the corresponding counter ions during the redox reaction of the electrochromic material and to maintain the charge balance of the entire system. The ion storage layer can be a photo inert ion storage layer that remains transparent when ionic charge injection/extraction occurs, such as TiO2, CeO2, SnO2 or ZrO2, or can be a photoactive electrochromic ion storage layer complementary to the material of the electrochromic layer 33, such as NiOx, IrO2, CoO2, MnO2, FeO2, Cr2O3 or RhO2, which can deepen the opaque effect of the ultraviolet ray mask in the light-shielding part.

The ultraviolet ray mask can further comprise two transparent protective layers 4 respectively disposed between the first polarizer 1 and the second substrate 32 and between the second polarizer 2 and the first substrate 31. The first polarizer 1 and the second polarizer 2 are respectively attached to surfaces of the two transparent protective layers 4. The two transparent protective layers 4 can be glasses used for protecting the electrochromic glass 3 in the middle. In other embodiments, the first substrate 31 and the second substrate 32 may be integrally formed with the transparent protective layers 4, respectively to eliminate two glass structures for reducing the overall thickness and simplifying the manufacturing process.

As shown in FIG. 4, the present invention further provides a manufacturing method of an ultraviolet ray mask, mainly comprising:

S01, providing a first underlayer 310, and sequentially fabricating the thin film transistors 31a and the second electrode layer 31b on the first underlayer 310, and the process of fabricating the thin film transistors 31a and the second electrode layer 31b on the first underlayer 310 is the same as the process of the conventional thin film transistor substrate, which will not be described in detail herein;

S02, providing a second underlayer 320, and fabricating the first electrode layer 32a on the second underlayer 320, and the first substrate 31 and the second substrate 32 adopt transparent glass substrates as the first underlayer 310 and the second underlayer 320, and the first electrode layer 32a and the second electrode layer 31b adopt transparent indium tin oxide material;

S03, filling material between the first underlayer 310 and the second underlayer 320 to form the electrochromic glass 3, and the electrochromic glass 3 specifically comprises the first substrate 31, the second substrate 32, an electrochromic layer 33 disposed between the first electrode layer 32a and the second electrode layer 31b, an electrolyte layer 34 disposed between the electrochromic layer 33 and the first electrode layer 32a and an ion storage layer 35 disposed between the electrochromic layer 33 and the second electrode layer 31b; and

S04, respectively attaching one transparent protective layer 4 on outer surfaces of the first underlayer 310 and the second underlayer 320, and then respectively attaching the first polarizer 1 and the second polarizer 2 on outer surfaces of the two transparent protective layers 4, and the transparent protective layers 4 can be glass.

In other embodiments, the transparent protective layers 4 may be eliminated or formed integrally with the first underlayer 310 and the second underlayer 320, which is advantageous for reducing the overall thickness and simplifying the manufacturing process.

The present invention provides the electrochromic glass with the thin film transistors and the electrode layers between two polarizers. By applying a voltage to the two electrode layers of the electrochromic glass, the transmittance of the electrochromic glass can be changed, so that the mask can be applied to products of various sizes, and the production cost of the panel is reduced to improve the panel production efficiency and to reduce the risk of fragmentation due to the replacement of the mask.

Above are only specific embodiments of the present application, the scope of the present application is not limited to this, and to any persons who are skilled in the art, change or replacement which is easily derived should be covered by the protected scope of the application. Thus, the protected scope of the application should go by the subject claims.

What is claimed is:

1. An ultraviolet ray mask, comprising a first polarizer and a second polarizer, which are oppositely arranged and an electrochromic glass disposed between the first polarizer and the second polarizer, wherein the electrochromic glass comprises a first substrate closer to the first polarizer and a second substrate closer to the second polarizer; a first electrode layer is provided on a surface of the first substrate facing the second substrate, and thin film transistors in an array and a second electrode layer disposed on the thin film transistors are provided on a surface of the second substrate facing the first substrate, and a transmittance of the electrochromic glass changes after a voltage is applied to the first electrode layer and the second electrode layer.

2. The ultraviolet ray mask according to claim 1, further comprising two transparent protective layers respectively disposed between the first polarizer and the second substrate and between the second polarizer and the first substrate.

3. The ultraviolet ray mask according to claim 1, wherein the electrochromic glass comprises the first substrate, the second substrate, an electrochromic layer disposed between the first electrode layer and the second electrode layer, an electrolyte layer disposed between the electrochromic layer and the first electrode layer and an ion storage layer disposed between the electrochromic layer and the second electrode layer.

4. The ultraviolet ray mask according to claim 3, further comprising two transparent protective layers respectively disposed between the first polarizer and the second substrate and between the second polarizer and the first substrate.

5. The ultraviolet ray mask according to claim 3, wherein the electrochromic layer is formed by tungsten trioxide.

6. The ultraviolet ray mask according to claim 3, wherein the electrochromic layer is formed by polythiophene and derivatives thereof, viologen, tetrathiafulvalene and metal phthalocyanine compound.

7. The ultraviolet ray mask according to claim 3, wherein the electrolyte layer is a solution or a solid electrolyte material containing lithium perchlorate or sodium perchlorate.

8. The ultraviolet ray mask according to claim 7, further comprising two transparent protective layers respectively disposed between the first polarizer and the second substrate and between the second polarizer and the first substrate.

9. The ultraviolet ray mask according to claim 3, wherein the ion storage layer is formed by one of TiO2, CeO2, SnO2 and ZrO2.

10. The ultraviolet ray mask according to claim 3, wherein the ion storage layer is formed by one of NiOx, IrO2, CoO2, MnO2, FeO2, Cr2O3 and RhO2.

11. The ultraviolet ray mask according to claim 1, wherein the first electrode layer and the second electrode layer are formed by indium tin oxide.

12. A manufacturing method of an ultraviolet ray mask, wherein the ultraviolet ray mask comprises a first polarizer and a second polarizer, which are oppositely arranged and an electrochromic glass disposed between the first polarizer and the second polarizer, and the electrochromic glass comprises a first substrate closer to the first polarizer and a second substrate closer to the second polarizer; a first electrode layer is provided on a surface of the first substrate facing the second substrate, and thin film transistors in an array and a second electrode layer disposed on the thin film transistors are provided on a surface of the second substrate facing the first substrate, and a transmittance of the electrochromic glass changes after a voltage is applied to the first electrode layer and the second electrode layer; the manufacturing method comprises:
providing a first underlayer, and sequentially fabricating the thin film transistors and the second electrode layer on the first underlayer;
providing a second underlayer, and fabricating the first electrode layer on the second underlayer;
filling material between the first underlayer and the second underlayer to form the electrochromic glass; and
respectively forming the first polarizer and the second polarizer on outer surfaces of the first underlayer and the second underlayer.

13. The manufacturing method of the ultraviolet ray mask according to claim 12, wherein the electrochromic glass comprises the first substrate, the second substrate, an electrochromic layer disposed between the first electrode layer and the second electrode layer, an electrolyte layer disposed between the electrochromic layer and the first electrode layer and an ion storage layer disposed between the electrochromic layer and the second electrode layer.

14. The manufacturing method of the ultraviolet ray mask according to claim 12, wherein the electrochromic layer is formed by tungsten trioxide.

15. The manufacturing method of the ultraviolet ray mask according to claim 12, wherein the electrochromic layer is formed by polythiophene and derivatives thereof, viologen, tetrathiafulvalene and metal phthalocyanine compound.

16. The manufacturing method of the ultraviolet ray mask according to claim 12, wherein the electrolyte layer is a solution or a solid electrolyte material containing lithium perchlorate or sodium perchlorate.

17. The manufacturing method of the ultraviolet ray mask according to claim 12, wherein the ion storage layer is formed by one of TiO2, CeO2, SnO2 and ZrO2.

18. The manufacturing method of the ultraviolet ray mask according to claim 12, wherein the ion storage layer is formed by one of NiOx, IrO2, CoO2, MnO2, FeO2, Cr2O3 and RhO2.

19. The manufacturing method of the ultraviolet ray mask according to claim 12, wherein the first electrode layer and the second electrode layer are formed by indium tin oxide.
